(19) United States
(12) Patent Application Publication
(10) Pub. No.: US 2021/0231716 A1
(43) Pub. Date: Jul. 29, 2021

(54) APPARATUS, METHODS AND COMPUTER-READABLE MEDIUM FOR EFFICIENT ELECTRICAL GRID MEASUREMENTS

(71) Applicants: University of Tennessee Research Foundation, Knoxville, TN (US); UT-Battelle (ORNL), Oak Ridge, TN (US)

(72) Inventors: Lingwei Zhan, Knoxville, TN (US); Bailu Xiao, Knoxville, TN (US); He Yin, Knoxville, TN (US); Fuhua Li, Knoxville, TN (US); Wenxuan Yao, Knoxville, TN (US); Zhi Li, Knoxville, TN (US); Thomas King, Knoxville, TN (US); Yilu Liu, Knoxville, TN (US)

(21) Appl. No.: 16/744,805

(22) Filed: Jan. 16, 2020

(51) Int. Cl. G01R 23/02

(52) U.S. Cl. CPC G01R 23/02

(57) ABSTRACT

Respective phasor values are recursively computed from respective ones of a series of signal samples for a node of a power system such that each phasor value is computed from a previously computed phasor value. Frequency values are recursively computed from the phasor values for respective ones of the signal samples. Recursive computing of frequency values may include computing respective phase angle values from respective ones of the phasor values, recursively computing coefficient values for a polynomial that fits the phase angle values, and recursively computing the frequency values from the coefficient values. The samples may be generated at a sampling rate and the phasor values and the frequency values may be produced at a rate that is the same as the sampling rate. Embodiments may provide methods, apparatus and computer readable media that implement such operations.

### STATEMENT OF GOVERNMENT SUPPORT

This invention was made with government support under Grant. No. EEC 1041877 by the National Science Foundation (NSF). The government has certain rights in the invention.

### BACKGROUND

The inventive subject matter relates to measurement of electrical parameters and, more particularly, to efficient computation of electrical parameters in AC systems.

The invention of Phasor Measurement Units (PMUs) have provided the grid operators a unique capability to monitor the power grid dynamics thanks to the synchronized and highly accurate measurements. Synchrophasor estimation processes are typically used in PMUs, with Discrete Fourier Transform (DFT) based measurement methods being widely used in commercial PMUs thanks to their good harmonic tolerance, high accuracy, and easy hardware implementation.

A typical maximum measurement rate of a commercial PMU is 60 Hz. The 2^{nd} generation Frequency Disturbance Recorders (FDRs) of FNET/GridEye have 10 Hz frequency measurement rate due to the high computation cost, and the measurement rate can reach to 60 Hz, at the expense of a hardware upgrade. A higher frequency measurement rate at the order of 1000 Hz or higher is desirable for some power protection, frequency-based load control, and faster system dynamic response prediction. However, improving the measurement rate from 60 Hz to the order of 1000 Hz or higher may tremendously increase hardware cost and retrofit expense for field device.

### SUMMARY

Some embodiments of the inventive subject matter provide methods including recursively computing respective phasor values from respective ones of a series of signal samples for a node of a power system such that each phasor value is computed from a previously computed phasor value. Frequency values are recursively computed from the phasor values for respective ones of the signal samples. Recursively computing frequency values may include computing respective phase angle values from respective ones of the phasor values, recursively computing coefficient values for a polynomial that fits the phase angle values, and computing the frequency values from the coefficient values. The samples may be generated at a sampling rate and the phasor values and the frequency values may be produced at a rate that is the same as the sampling rate. Further embodiments may provide apparatus and computer readable media configured to perform such methods.

According to some embodiments, recursively computing frequency values may include computing a first phase angle value from a first phasor value for a first sample, computing a first value for a coefficient of a polynomial that fits the phase angle value from the first phase angle value, computing a first frequency value for the first sample from the first value for the coefficient, computing a second phase angle value for a second phasor value for a second sample, computing a second value for the coefficient from the second phase angle value, and computing a second frequency value for the second sample from the second value for the coefficient and the first frequency value.

In some embodiments, recursively computing frequency values may be preceded by computing a plurality of phasor values from a set of signal samples, computing a plurality of phase angle values from the plurality of phasor values, and computing a frequency value from the plurality of phase angle values.

Further embodiments provide methods including computing a plurality of first phase angle values from a plurality of first signal samples, computing a first value for a coefficient of a polynomial that fits the first phase angle values, computing a first frequency value from the first value for the coefficient, computing a second phase angle value from a second signal sample, computing a second value for the coefficient from the first value for the coefficient and the second phase angle value, and computing a second frequency value from the second value for the coefficient. Computing the plurality of first phase angle values may include recursively computing a plurality of first phasor values for respective ones of the first signal samples such that each of the first phasor values is computed from a previously computed one of the first phasor values, and computing the plurality of first phase angle values from the first phasor values. Computing the second phase angle value from the second signal sample may include computing a second phasor value from one of the first phasor values and the second sample and computing the second phase angle value from the second phasor value.

According to some embodiments, recursively computing the plurality of first phasor values for respective ones of the first signal samples may be preceded by computing an initial phasor value from an initial plurality of signal samples using a discrete Fourier transform (DFT). Recursively computing the plurality of first phasor values for respective ones of the first signal samples may include computing a first one of the first phasor values from the initial phasor value.

According to further embodiments, the methods may further include computing a third phase angle value from a plurality of third signal samples, computing a third value for the coefficient from the second value for the coefficient and the third phase angle value, and computing a third frequency value from the second frequency value and the third value for the coefficient.

Still further embodiments provide apparatus including a sensor circuit coupled to a node of an electrical power system and configured to generate a series of samples of a signal at the node. The apparatus further includes a data processor configured to recursively compute respective phasor values from respective ones of a series of signal samples for the node such that each phasor value is computed from a previously computed phasor value and to recursively compute frequency values from the phasor values for respective ones of the signal samples.

### BRIEF DESCRIPTION OF THE DRAWINGS

FIG. 1 is a flow diagram illustrating operations for measuring an electrical signal according to some embodiments.

FIG. 2 is a flow diagram illustrating operations for measuring an electrical signal according to further embodiments.

FIG. 3 is a schematic diagram illustrating an apparatus for measuring an electrical signal according to some embodiments.

FIGS. 4-11 are graphs illustrating performance characteristics of apparatus, methods and computer readable media according to some embodiments.

### DETAILED DESCRIPTION

Specific exemplary embodiments of the inventive subject matter now will be described with reference to the accompanying drawings. This inventive subject matter may, however, be embodied in many different forms and should not be construed as limited to the embodiments set forth herein; rather, these embodiments are provided so that this disclosure will be thorough and complete, and will fully convey the scope of the inventive subject matter to those skilled in the art. In the drawings, like numbers refer to like items. It will be understood that when an item is referred to as being “connected” or “coupled” to another item, it can be directly connected or coupled to the other item or intervening items may be present. As used herein the term “and/or” includes any and all combinations of one or more of the associated listed items.

The terminology used herein is for the purpose of describing particular embodiments only and is not intended to be limiting of the inventive subject matter. As used herein, the singular forms “a”, “an” and “the” are intended to include the plural forms as well, unless expressly stated otherwise. It will be further understood that the terms “includes,” “comprises,” “including” and/or “comprising,” when used in this specification, specify the presence of stated features, integers, steps, operations, items, and/or components, but do not preclude the presence or addition of one or more other features, integers, steps, operations, items, components, and/or groups thereof.

Unless otherwise defined, all terms (including technical and scientific terms) used herein have the same meaning as commonly understood by one of ordinary skill in the art to which this inventive subject matter belongs. It will be further understood that terms, such as those defined in commonly used dictionaries, should be interpreted as having a meaning that is consistent with their meaning in the context of the specification and the relevant art and will not be interpreted in an idealized or overly formal sense unless expressly so defined herein.

As will be appreciated by one of skill in the art, the inventive subject matter may be embodied as a method, data processing system, or computer readable media (computer program product) having program code (computer instructions) embodied therein that is configured to execute on a computer or other data processing device. Accordingly, the present inventive subject matter may take the form of an entirely hardware embodiment or an embodiment combining software and hardware aspects all generally referred to herein as a “circuit” or “module.” Furthermore, the present inventive subject matter may take the form of a computer-readable medium. Any suitable computer readable medium may be utilized including non-volatile solid-state memory, hard disks, CD-ROMs, optical storage devices, a transmission media such as those supporting the Internet or an intranet, or magnetic storage devices. The program code may execute entirely on a single data processing device or multiple data processing devices, which may be connected through a network, such as a local area network (LAN) or a wide area network (WAN).

The inventive subject matter is described in part below with reference to flowchart illustrations and/or block diagrams of methods, systems and computer-readable media according to embodiments of the inventive subject matter. It will be understood that each block of the illustrations, and combinations of blocks, can be implemented by program code. The program code may be provided to a data processor of a general purpose computer, special purpose data processing device (e.g., a microcontroller), or other programmable data processing apparatus to produce a machine, such that the program code executes on the data processing apparatus to create an apparatus that implements the functions/acts specified in the block or blocks.

These computer program instructions may also be stored in a computer-readable media that can direct a data processing apparatus to function in a particular manner, such that the instructions stored in the computer-readable media constitute an article of manufacture including program code that implements the functions/acts specified in the block or blocks. The computer program code may also be loaded onto a computer or other data processing apparatus to cause a series of operational steps to be performed on the computer or other programmable apparatus to produce a computer implemented process such that the instructions which execute on the data processing apparatus provide steps that implement the functions/acts specified in the block or blocks.

Instead of solving the challenge of obtaining higher grid parameter measurement rates through hardware upgrades, some embodiments of the inventive subject matter can provide more computationally efficient and accurate measurement processes that can enable device cost reduction, large volume device deployment, and high-rate measurements, which can ultimately contribute to situational awareness and grid visibility improvement. Methods, apparatus and computer-readable media according to some aspects of the inventive subject matter can provide ultra-fast and accurate grid frequency measurements. In some embodiments, a computational complexity of such techniques in Big O notation is O(1)(i.e. constant time, and independent of window size), and a new frequency can be estimated using a limited number of numerical operations. Some embodiments may provide very high measurement accuracy, as verified for several different types of steady-state and dynamic signals.

In particular, some embodiments may provide low computation costs, which in some applications can save computational resources for other functions. Using fewer computational resources may result in lower hardware cost to achieve the same measurement performance (i.e. measurement accuracy and measurement rate) as conventional DFT-based frequency estimation techniques. With lower computational cost, some embodiments may be more easily integrated into grid devices such as relays, smart meters, Distributed Energy Resources (DERs), and the like, so these devices can provide a measurement accuracy that is comparable to that provided by PMUs.

Some embodiments of the inventive subject matter provide ultra-fast and accurate grid frequency measurements. Denoting complexity in Big O notation is O(1) (i.e. constant time, and independent of window size), new frequency values can be generated using a relatively low number of operations, thus improving the efficiency of a phase measurement unit or other device that utilizes these techniques. The measurements may also exhibit a high level of accuracy, as has been indicated in tests for different types of steady-state and dynamic signals. In some hardware platforms, methods and apparatus according to some embodiments may save computational resources for other functions. Some embodiments may use less computational resource that conventional approaches (such as conventional DFT-based approaches), and thus may entail lower hardware cost to achieve comparable measurement performance. As such, methods and apparatus according to some embodiments may be more readily integrated into grid devices, such as relays, smart meters, distributed energy resources, and the like, so these devices can have measurement performance comparable to that provided by PMUs. Some embodiments may provide frequency estimates that reach to the data sampling rate, and thus provide orders of higher grid visibility than state-of-the-art approaches. Some embodiments provide high-density measurement data, which can provide high resolution data for power event analysis, real-time control and more reliable protection, and the like. The relatively high frequency measurement rate capability can enable determination of the rate of change of frequency with high accuracy.

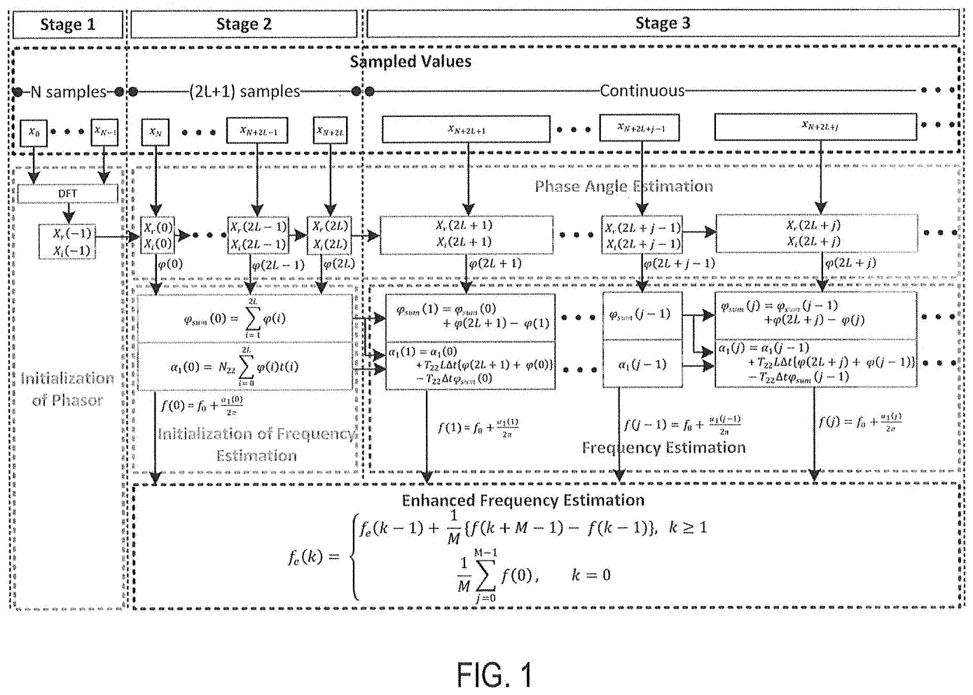

The sampled values of single-phase grid voltage waveform can be expressed by

$${x}_{k} = A cos ( 2 π f \frac{k}{{f}_{c} N} + θ ) \qquad ( 1 )$$

where k is the index of sampled values of the grid voltage or current waveform, f is the fundamental frequency of the power grid, f₀ is the nominal frequency of the power grid, N is the number of sampled values in one fundamental frequency period (i.e. 1/f₀), f₀N is the sampling rate of sampled values, θ is the initial phase angle at time zero. A process for generating frequency estimates may be viewed as including four parts, as illustrated in FIG. 1.

### Initialization of Phasor

The DFT of the sampled values xₖ over N samples (i.e. one fundamental frequency), k⊂[0,N−1] can be expressed by

$$\{ \begin{matrix}{X}_{r} ( - 1 ) = \frac{1}{\sqrt{2}} \frac{2}{N} {\sum }_{k = 0}^{N - 1} {ϰ}_{k} cos ( \frac{2 π k}{N} ) \\ {X}_{i} ( - 1 ) = \frac{1}{\sqrt{2}} \frac{2}{N} {\sum }_{k = 0}^{N - 1} {ϰ}_{k} sin ( - \frac{2 π k}{N} )\end{matrix} \qquad ( 2 )$$

where Xᵣ(−1) is the real part of the DFT, and Xᵢ(−1) is the imaginary part of the DFT. Note that the index starts from −1, and it is for the sake of simplicity of the following mathematical derivations.

### Phase Angle Estimation

By applying recursive DFT on the sampled values at index k=N, we have

$$\{ \begin{matrix}{X}_{r} ( 0 ) = {X}_{r} ( - 1 ) + \frac{1}{\sqrt{2}} \frac{2}{N} ( {x}_{N} - {x}_{0} ) cos ( \frac{2 π N}{M} ) \\ {X}_{i} ( 0 ) = {X}_{i} ( - 1 ) + \frac{1}{\sqrt{2}} \frac{2}{N} ( {x}_{N} - {x}_{0} ) sin ( - \frac{2 π N}{N} )\end{matrix} , \qquad ( 3 )$$

For any m≥0, the phasor can be calculated by

$$\{ \begin{matrix}{X}_{r} ( m ) = {X}_{r} ( m - 1 ) + \frac{1}{\sqrt{2}} \frac{2}{N} ( {x}_{m - N} - {x}_{m} ) cos ( \frac{2 π m - N }{N} ) \\ {X}_{i} ( m ) = {X}_{i} ( m - 1 ) + \frac{1}{\sqrt{2}} \frac{2}{N} ( {x}_{m - N} - {x}_{m} ) sin ( - \frac{2 π m - N }{N} )\end{matrix} . \qquad ( 4 )$$

Note that once we have Xᵣ(m−1), and Xᵢ(m−1), Xᵣ(m) and Xᵢ(m) can be calculated recursively in constant time by just two numerical operations (i.e., one subtraction and one multiplication).

Then, the phase angle can be calculated by

$$φ ( m ) = arctan ( \frac{{x}_{i} ( m )}{{x}_{r} ( m )} ) , m \geq 0. \qquad ( 5 )$$

Note that the computation time of inverse tangent function arctan in (5) is also constant time. In summary, when Xᵣ(−1) and Xᵢ(−1) are obtained, by using (4) and (5), a new phase angle can be calculated recursively in constant time. Thus, the computational complexity of estimating a new phase angle φ(m), m≥0 in Big O notation is O(1). In addition, according to (4), a new phase angle can be estimated when a new sampled value is available, therefore the phase angle estimation rate is the same as the sampling rate (i.e., f₀N).

### Initialization of Frequency Estimation

By the definition of recursive DFT, derivative of φ(m) is equal to the deviation of angular speed from nominal angular speed, which can be expressed by

$$\begin{matrix}{φ}^{′} ( m ) = \frac{φ ( m ) - φ ( m - 1 )}{Δ t} \\ = 2 π ( f ( m ) - {f}_{0} ) , m \geq 0\end{matrix} \qquad ( 6 )$$

where Δt is the sampling period, and it is equal to 1/(f₀N).

According to (6), the frequency of power grid, denoted by f(m), can be estimated by φ(m) and φ(m−1). However, the power grid waveforms are always distorted by a variety of disturbances such as noise, harmonics, oscillation, etc. Therefore, in practice, usually a series of phase angles are used for the frequency estimation.

First, assuming the number of phase angles used for one frequency estimation is (2L+1). A quadratic polynomial is to fit these phase angles, and the quadratic polynomial is expressed by

p(i)=α₀+α₁t(i)+α₂t(t)²,t=0, . . . ,2L (7)

where α₀, α₁, α₂ are the coefficients of the quadratic polynomial, t(i)=(i−L)Δt. It will be appreciated that fitting of the phase angles to a polynomial may include “unwrapping” of the phase angle values (e.g., by augmentation by an appropriate multiple of 2π).

The derivate of p(i) can be expressed by

p′(i)=α₁+2α₂t(i). (8)

Further, at sample index i=L,

p′(L)=α₁. (9)

Therefore, the frequency at sample index i=L can be calculated by

$$f = {f}_{0} + \frac{{α}_{1}}{2 π} \qquad ( 10 )$$

According to (10), we only need estimate the coefficient α₁ (the “first order term coefficient” of the polynomial) to estimate frequency. The curve fitting errors are minimized to estimate α₁. Using the estimated phase angle φ(i) and the fitting curve p(i), the sum of the square of the error can be expressed by

e=ϵ(α₀,α₁,α₂)=Σ₀^{2L}(p(i)−φ(i))². (11)

To minimize the error e, the partial derivatives of e with respect to the coefficients α₀, α₁, α₂ should be equal to zero, respectively.

The equation resulting from evaluating the partial derivative of e with respect to α₀, α₁, and α₂ are presented as follows. The details of the derivations are introduced in the Appendix below.

$$\begin{matrix}\frac{\partial e}{\partial {α}_{0}} = 2 {α}_{0} ( 2 L + 1 ) + 2 {α}_{1} {\sum }_{i = 0}^{2 L} t ( i ) + 2 {α}_{2} {\sum }_{i = 0}^{2 L} {t ( i )}^{2} - 2 {\sum }_{i = 0}^{2 L} φ ( i ) & ( 12 ) \\ \frac{\partial e}{\partial {α}_{1}} = 2 {α}_{0} {\sum }_{i = 0}^{2 L} t ( i ) + 2 {α}_{1} {\sum }_{i = 0}^{2 L} {t ( i )}^{2} + 2 {α}_{2} {\sum }_{i = 0}^{2 L} {t ( i )}^{2} - 2 {\sum }_{i = 0}^{2 L} φ ( i ) t ( i ) & ( 13 ) \\ \frac{\partial e}{\partial {α}_{2}} = 2 {α}_{0} {\sum }_{i = 0}^{2 L} {t ( i )}^{2} + 2 {α}_{1} {\sum }_{i = 0}^{2 L} {t ( i )}^{3} + 2 {α}_{2} {\sum }_{i = 0}^{2 L} {t ( i )}^{4} - 2 {\sum }_{i = 0}^{2 L} φ ( i ) {t ( i )}^{2} & ( 14 )\end{matrix}$$

The error e is minimized when the derivatives are equal to zero (i.e.

$$\frac{\partial \text{?}}{\partial \text{?}} = \frac{\partial \text{?}}{\partial \text{?}} = \frac{\partial \text{?}}{\partial \text{?}} = 0 ) , \\ \text{?} \text{indicates text missing or illegible when filed}$$

thus,

$$[ \begin{matrix}( 2 L + 1 ) & \text{?} t ( i ) & \text{?} {t ( i )}^{2} \\ \text{?} t ( i ) & \text{?} {t ( i )}^{2} & \text{?} {t ( i )}^{2} \\ \text{?} {t ( i )}^{3} & \text{?} {t ( i )}^{3} & \text{?} {t ( i )}^{3}\end{matrix} ] [ \begin{matrix}{α}_{0} \\ {α}_{1} \\ {α}_{2}\end{matrix} ] = [ \begin{matrix}\text{?} φ ( i ) \\ \text{?} φ ( i ) t ( i ) \\ \text{?} φ ( i ) {t ( i )}^{2}\end{matrix} ] \\ \text{?} \text{indicates text missing or illegible when filed} \qquad ( 15 )$$

Because t(i)=(i−L)Δt,

Σᵢ₌₀^{2L}t(i)=Σᵢ₌₀^{2L}t(i)²=0. (16)

Therefore, (15) can be written as

$$[ \begin{matrix}( 2 L + 1 ) & 0 & {\sum }_{i = 0}^{2 L} {t ( i )}^{1} \\ 0 & {\sum }_{i = 0}^{2 L} {t ( i )}^{3} & 0 \\ {\sum }_{i = 0}^{2 L} {t ( i )}^{2} & 0 & {\sum }_{i = 0}^{2 L} {t ( i )}^{4}\end{matrix} ] [ \begin{matrix}{α}_{1} \\ {α}_{2} \\ {α}_{3}\end{matrix} ] = [ \begin{matrix}{\sum }_{i = 0}^{2 L} φ ( i ) \\ {\sum }_{i = 0}^{2 L} φ ( i ) t ( i ) \\ {\sum }_{i = 0}^{2 L} φ ( i ) {t ( i )}^{2}\end{matrix} ] \qquad ( 17 )$$

Simplify the above equation as

Tα=φ (18)

Then, applying T⁻¹ on both sides yields:

α=T⁻¹φ (19)

where T⁻¹ is the inverse of matrix T. (19) can be expanded as

$$[ \begin{matrix}{α}_{0} \\ {α}_{1} \\ {α}_{2}\end{matrix} ] = [ \begin{matrix}{T}_{11} & {T}_{12} & {T}_{13} \\ {T}_{21} & {T}_{22} & {T}_{23} \\ {T}_{31} & {T}_{32} & {T}_{33}\end{matrix} ] [ \begin{matrix}{\sum }_{i = 0}^{2 L} φ ( i ) \\ {\sum }_{i = 0}^{2 L} φ ( i ) t ( i ) \\ {\sum }_{i = 0}^{2 L} φ ( i ) {t ( i )}^{3}\end{matrix} ] \qquad ( 20 )$$

where Tᵢⱼ is the entry of matrix T⁻¹.

Because only α₁ is needed for frequency estimation, only T₂₁, T₂₂, and T₂₃ in T⁻¹ need to be calculated, which are as follows:

$$\begin{matrix} {T}_{21} = \frac{1}{det ( \text{?} )} \vert \begin{matrix}0 & \text{?} {t ( i )}^{2} \\ 0 & \text{?} {t ( i )}^{4}\end{matrix} \vert = 0 & ( 21 ) \\ {T}_{22} = \frac{1}{det ( \text{?}} \vert \begin{matrix}2 L + 1 & \text{?} {t ( i )}^{2} \\ \text{?} {t ( i )}^{2} & \text{?} {t ( i )}^{4}\end{matrix} \vert = \frac{( 2 L + 1 ) \text{?} {t ( i )}^{4} - {( \text{?} {t ( i )}^{2} )}^{2}}{det ( \text{?} )} & ( 22 ) \\ {T}_{23} = - \frac{1}{det ( \text{?} )} \vert \begin{matrix}2 L + 1 & 0 \\ \text{?} {t ( i )}^{2} & 0\end{matrix} \vert = 0 \\ \text{?} \text{indicates text missing or illegible when filed} & ( 23 )\end{matrix}$$

where det(T⁻¹) is the determinant of T⁻¹.

Since T₂₁=T₂₃=0, α₁ can be expressed by

$${α}_{1} = {T}_{21} \text{?} φ ( i ) + {T}_{22} \text{?} φ ( i ) t ( i ) + {T}_{23} \text{?} φ ( i ) t ( i ) \text{?} = {T}_{23} \text{?} φ ( i ) t ( i ) . \\ \text{?} \text{indicates text missing or illegible when filed} \qquad ( 24 )$$

Note that T₂₂ only depends on the parameters of L and Δt, which are constant parameters, so it can be calculated offline.

### Frequency Estimation

Typically, using (10) and (24), a new frequency can be estimated using a total number of (2L+1) phase angles. We can see the computation time for a new frequency estimation is proportional to L since it requires (2L+1) multiplications and 2L additions in (24). Therefore, although the computational complexity of phase angle estimation is O(1), the computational complexity of frequency estimation is O(L).

Now we can conclude that the bottleneck of the frequency computing time is the computation of α₁. If we could reduce the computation time of α₁ from O(L) to O(1)(i.e. constant time and independent of L), we could achieve the frequency estimation in O(1) computational complexity.

To calculate α₁ in O(1) computational complexity, we need try compute α₁ recursively. First, let us use α₁(j) to denote α₁, and it can be expressed by

α₁(j)=T₂₂Σᵢ₌₀^{2L}φ(i+j)t(i). (25)

The first α₁, which is α₁(0), can be calculated using (25) in linear time proportional to L. Then for j≥1, (26) can be deduced, with the details are presented in the Appendix (below).

$${α}_{1} ( j ) - {α}_{1} ( j - 1 ) = \text{?} L Δ t \{ φ ( 2 L + j ) + φ ( j - 1 ) \} - \text{?} Δ t \text{?} φ ( i + j - 1 ) \\ \text{?} \text{indicates text missing or illegible when filed} \qquad ( 26 )$$

Further, let us define

$$\text{?} ( j - 1 ) = \text{?} φ ( i + j - 1 ) , \\ j \geq 1 , \\ \text{?} \text{indicates text missing or illegible when filed} \qquad ( 27 )$$

then (26) can rewritten as

$${α}_{1} ( j ) - {α}_{1} ( j - 1 ) = \text{?} L Δ t \{ φ ( 2 L + j ) + φ ( j - 1 ) \} - \text{?} Δ t \text{?} ( j - 1 ) . \\ \text{?} \text{indicates text missing or illegible when filed} \qquad ( 28 )$$

According to (28), a new α₁, denoted by α₁(j), can be computed from a previous α₁, denoted by α₁(j−1). As T₂₂LΔt is a constant, the first term T₂₂LΔt[φ(2L+j)+φ(j−1)] in (28) can be computed in constant time by one addition and one multiplication. For the second term T₂₂Δtφₛᵤₘ (j−1), according to (27), the computation time of φₛᵤₘ(j−1) is proportional to L, so it still has the O(L) computational complexity. However, by using a sliding window method, we can reduce the computational complexity of φₛᵤₘ(j−1) from O(L) to O(1). To be specific, according to (27), for j≥2, we have

$$\text{?} ( j - 1 ) = \text{?} ( j - 2 ) + φ ( 2 L + j - 1 ) - φ ( j - 1 ) . \\ \text{?} \text{indicates text missing or illegible when filed} \qquad ( 29 )$$

Therefore, according to (29), once we have φₛᵤₘ(0), φₛᵤₘ(j−1), j≥2 can be computed in constant time by one addition and one subtraction. In brief, with α₁(j−1), a new α₁(j), thus a new frequency can be computed in constant time with O(1) time complexity.

### Enhanced Frequency Estimation

To further reduce the measurement errors of the frequency estimated by (10), these frequencies could pass through a moving average filter as follows:

$$\text{?} ( k ) = \frac{1}{M} {\sum }_{j = k}^{k + M - 1} f ( j ) , \\ k \geq 0 , \\ j \geq k \\ \text{?} \text{indicates text missing or illegible when filed} \qquad ( 30 )$$

where fₑ(k) is the enhanced frequency measurement by the moving averaging filter, M is the window size of the filter, f(j) is calculated by (10).

Further, (30) can also be rewritten as

$$\text{?} ( k ) = \{ \begin{matrix}\text{?} ( k - 1 ) + \frac{1}{M} \{ f ( k + M - 1 ) - f ( k - 1 ) \} , & k \geq 1 \\ \frac{1}{M} \text{?} f ( 0 ) , & k = 0\end{matrix} . \\ \text{?} \text{indicates text missing or illegible when filed} \qquad ( 31 )$$

Note that by having fₙ(k−1), the enhanced frequency fₙ(k) can also be computed in constant time by one multiplication and one subtraction, which also has O(1) time complexity.

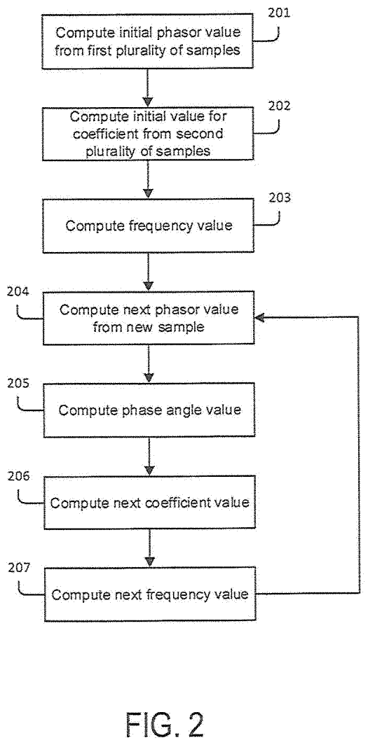

FIG. 2 illustrates operations according to some embodiments. An initial phasor value is computed from a first plurality of samples (block 201), along the lines of “Stage 1” illustrated in FIG. 1. An initial value for a coefficient of a polynomial that fits phase angle values generated from a second plurality of samples is computed (block 202), along the lines of “Stage 2” of FIG. 1. An initial frequency value may be computed from the initial value of the coefficient (block 203).

Subsequently, phasor values and frequency values may be recursively generated along the lines of “Stage 3” of FIG. 1. A new phasor value is computed from a next sample (block 204). A phase angle value is computed from the new phasor value (block 205) and used to compute a new value for the coefficient (block 206). A new frequency value is computed from the new value for the coefficient (block 207). These operations may be repeated for each subsequent sample.

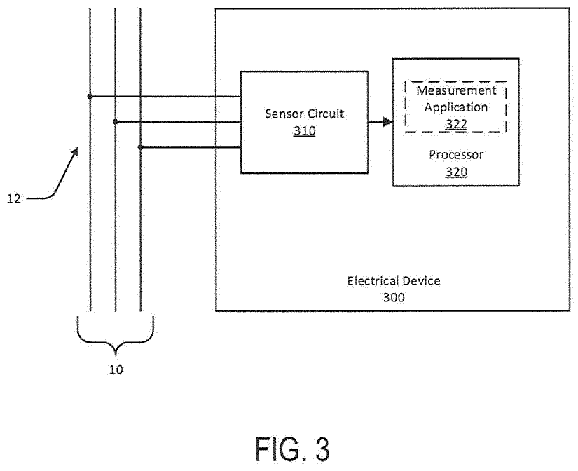

FIG. 3 illustrates an apparatus according to some embodiments. The apparatus includes an electrical device 300, such as a PMU or other electrical equipment, that is coupled to a node 12 of an electrical grid 10. The device 300 includes sensor circuitry 310 that is configured to sense a voltage or other signal at the node 12 and to generate signal samples therefrom. The sensor circuitry 310 may include, for example, transformers, signal conditioning circuitry, analog to digital conversion circuitry, and the like. Samples generated by the sensor circuitry 310 are provided to a data processor 320, e.g., a microprocessor or microcontroller. A measurement application 322 executes on the data processor 320 to create an apparatus that executes a process along the lines discussed above with reference to FIGS. 1 and 2. It will be appreciated that the measurements generated by the application may be used internally, e.g., in another application executed by the processor 320, and/or may be communicated to a recipient external to the device 300.

### Computational Complexity

The computational complexity in Big O notation of some embodiments is presented in Table I. This table summarizes all the variables that need to be computed for frequency estimation, and they can be divided into two groups based on the number of times it needs to be computed. The variables in the first group only need to be computed once, and the variables in the second group need to be computed continuously. For each, variable, the table lists the corresponding equation and its computational complexity in Big O notation. It should be noted that the variables in the first group only need to be computed once when the process starts to run, so it does not contribute to the computational complexity of the process. In fact, the variables in the second group will determine the computational complexity. Because all the variables in this group have O(1) computational complexity, the process has O(1) computational complexity.

TABLE I
Computational Complexity Analysis

| | | | Computational |
|---|---|---|---|
| Count | Variable | Equation | Complexity |
| once | X [symbol] (−1) | (2) | O(N) |
| | X [symbol] (−1) | (2) | O(N) |
| | | (27) for | |
| | φ [symbol] (0) | [symbol] = 0 | O(L) |
| | | (25) for | |
| | α [symbol] (0) | [symbol] = 0 | O(L) |
| | | (31) for | |
| | f [symbol] (0) | k = 0 | O(M) |
| continuous | X [symbol] (m), m ≥ 0 | (4) | O(1) |
| | X [symbol] ( [symbol] s), m ≥ 0 | (4) | O(1) |
| | φ(m), m ≥ 0 | (5) | O(1) |
| | φ [symbol] ( [symbol] − 1), [symbol] | (29) | O(1) |
| | α [symbol] (j) [symbol] j ≥ 1 | (28) | O(1) |
| | f( [symbol] ) [symbol] j ≥ 0 | (10) | O(1) |
| | f [symbol] (j), j ≥ 1 | (31) | O(1) |

[symbol]

indicates data missing or illegible when filed

The actual number of numerical operations of the variables in the second group is summarized in Table II. It should be noted if we have a multiplication of multiple constant parameters, we can compute the multiplication offline and save the result as a constant to reduce the computation time. According to Table II, a new frequency can be estimated very fast by just using 12 ‘+/−’ operations, 6 ‘*’ operations, and 1 arctan operation.

TABLE II
Number of numerical operations

| | | count | | |
|---|---|---|---|---|
| | | of ‘+’ | count | count |
| Variable | Equation | and ‘−’ | of ‘*’ | of arctan |
| X [symbol] j(m), m ≥ 0 | (4) | 2 | 1 | 0 |
| X [symbol] (m), m ≥ 0 | (4) | 2 | 1 | 0 |
| φ(m), m ≥ 0 | (5) | 0 | 0 | 1 |
| φ [symbol] (f − 1) [symbol] ≥ 2 | (29) | 2 | 0 | 0 |
| [symbol] ( [symbol] ) [symbol] ≥ 1 | (28) | 3 | 2 | 0 |
| f( [symbol] ) [symbol] ≥ 0 | (10) | 1 | 1 | 0 |
| f [symbol] ( [symbol] ) [symbol] ≥ 1 | (31) | 2 | 1 | 0 |
| Total | N/A | 12 | 6 | 1 |

[symbol]

indicates data missing or illegible when filed

### Computation Time Evaluation

The computation time of some embodiments has been evaluated on a 3.6 GHz 4-core computer. The computation time of a classic DFT based process has been also tested for performance comparison. Different process window size and sampling rate were considered, and the computation times of 1000 frequencies are presented in Table III. The computation time of a conventional DFT process may increase linearly with the window size and sampling rate. In a contrast, the computation time of the evaluated embodiments may be independent of sampling rate and window size, which verifies the O(1) computational complexity. At 1440 Hz sampling rate, for a commonly used 5-cycle window size, the evaluated embodiments are about 640× faster, and increases to 2300× faster for a 20-cycle window size. Some embodiments have a three orders of magnitude computation speed advantage over a conventional DFT-based process.

TABLE III
Computation Time Test

| | | Computation Time (second) | | |
|---|---|---|---|---|
| Sampling | Window Size | DFT | Proposed | |
| Rate | (cycle) | Process | Process | Faster |
| 1440 Hz | 5 | 1.279 | 0.002 | 650x |
| | 10 | 2.396 | 0.002 | 1200x |
| | 20 | 4.611 | 0.002 | 2300x |
| 2880 Hz | 5 | 2.590 | 0.002 | 1300x |
| | 10 | 4.870 | 0.002 | 2400x |
| | 20 | 9.240 | 0.002 | 4600x |

### Measurement Accuracy

Measurement accuracy of some embodiments was evaluated using different types of steady-state and dynamic test signals according to IEC/IEEE 60255-118-1 for M class PMUs. The parameters of the evaluated embodiments are summarized in Table IV. As N is equal to 24, the sampling rate is 1440 Hz. The number of phase angle used for one frequency estimation is equal to 121 (=2L+1). The window size of the moving averaging filter is 12. The frequency estimation rate is equal to the data sampling rate of 1400 Hz.

TABLE IVV
Parameters of the proposed process

| N | L | M |
|---|---|---|
| 24 | 60 | 12 |

### Frequency Range Test

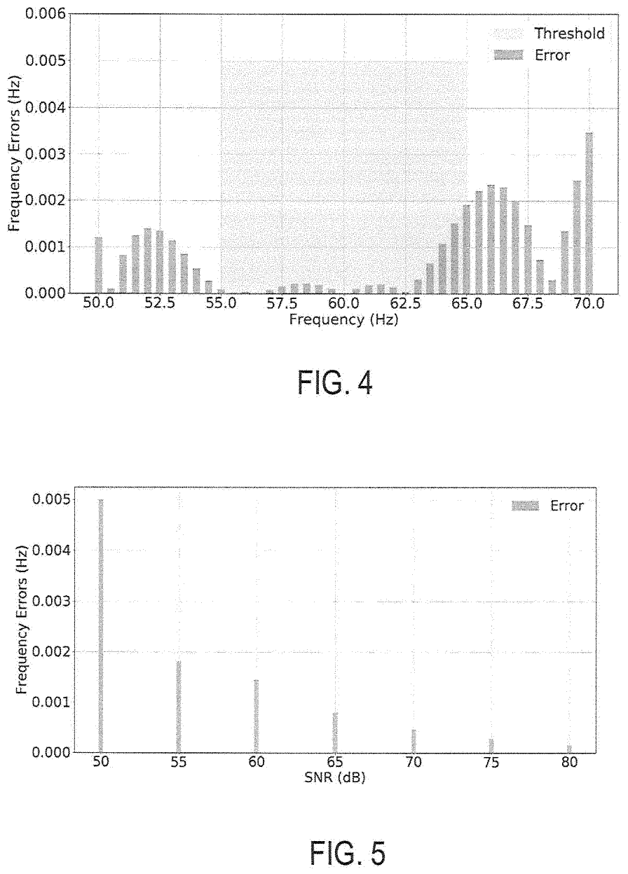

In this test, the frequency of the test signal varies from 50 to 70 Hz at a step of 0.25 Hz, and the measurement errors are shown in FIG. 4. In FIG. 4, the x-axis shows the frequency of the test signal, and the y-axis shows frequency measurement errors. The dark bars represent the maximum frequency measurement error of the algorithm at each frequency, and the lighter block represents a measurement error threshold, with a measurement error less than 0.005 Hz being desirable in a maximum frequency measurement range from 55 to 65 Hz. As shown in FIG. 3, the measurement errors of the algorithm are below 0.005 Hz between 55 Hz and 65 Hz. The embodiments also meet the 0.005 Hz error threshold in a boarder frequency range from 50 Hz to 70 Hz.

### Noise Tolerance Test

In this test, different level of noise from 50 dB to 80 dB at a step of 5 dB is added to a clean 60 Hz test signal, with the testing results shown in FIG. 5. The measurement error at 50 dB noise is about 5 mHz and decreases to about 0.15 mHz at 80 dB noise. In practice, the noise level at distribution network may be about 60-70 dB, and the dB level of noise at the transmission network is typically higher. At 65 dB noise, the measurement error is less than 1 mHz. For a conventional window-based estimation process, such as DFT, the noise tolerance performance usually depends on the window size. The errors would likely decrease with the increase of the window size, and vice versa.

### Harmonic Distortion Test

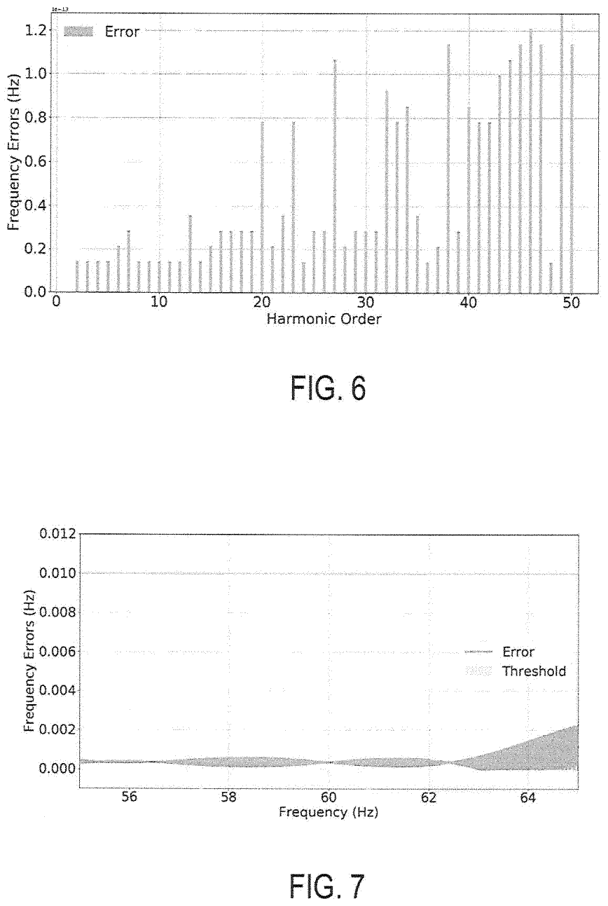

In this test, different order of harmonic component from 2^{nd} to 50^{th} is added to a 60 Hz test signal, with the testing results shown in FIG. 6. As the DFT based algorithms usually have strong harmonic distortion immunity, the evaluated embodiments may inherit this feature and perform very well under harmonic distortions. It should be noted that the numbers in y-axis is in the scale of 1e⁻¹³, so the measurement errors are in fact substantially equal to 0 Hz.

### Frequency Ramp Test

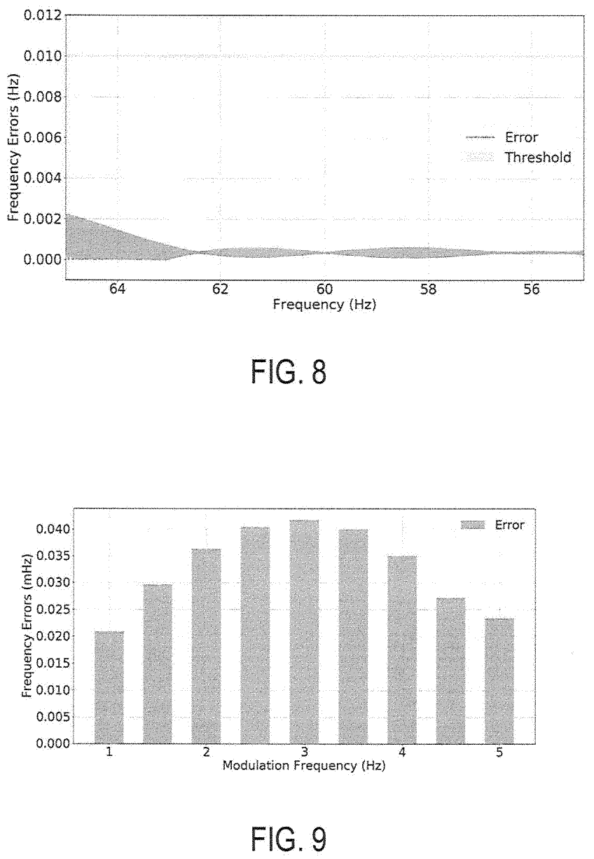

In this test, the frequency of the test signal ramps up from 59 Hz to 61 Hz at a rate of 1 Hz/s, and then ramps down from 61 Hz to 59 Hz at a rate of −1 Hz/s. The testing results are shown in FIG. 7 and FIG. 8, respectively. The maximum measurement errors for both ramp up and ramp down are below 2.5 mHz. By comparing FIG. 7 and FIG. 8 with FIG. 4, we could find for the frequency ramp test, the measurement errors may be mainly caused by the frequency deviation from nominal frequency, instead of the frequency ramp.

### Magnitude Modulation Test

In this test, a magnitude modulation signal is applied to the 60 Hz signal, the magnitude of the modulation signal is 10% of the fundamental 60 Hz signal, and the modulation frequency varies from 1 Hz to 5 Hz at a step of 0.5 Hz. The measurement errors are shown in FIG. 9. The measurement errors are less than 0.04 mHz. The error threshold has a range from 0.12 to 0.3 Hz, which is determined by the measurement rate. The error thresholds are not shown in the figure as the measurement errors are negligible with respect to the error thresholds.

### Phase Modulation Test

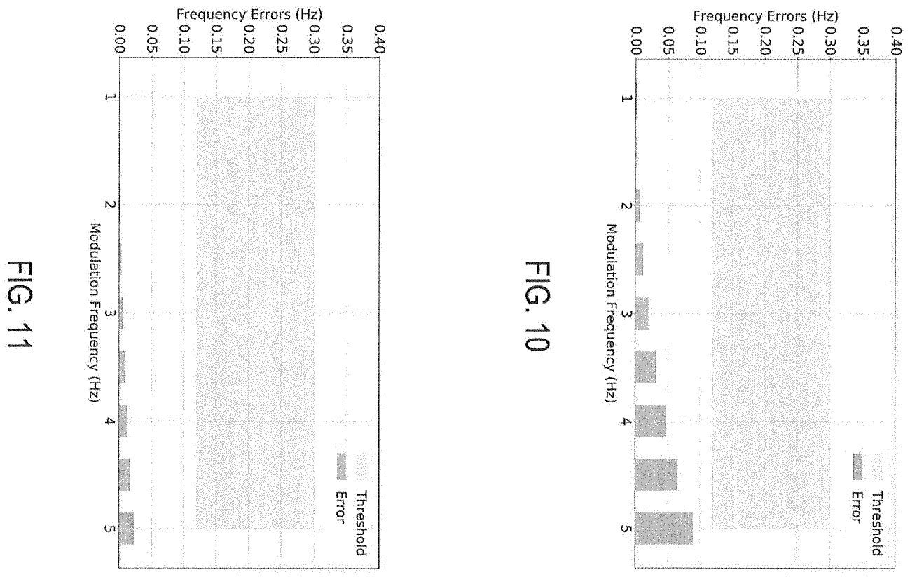

In this test, a phase angle modulation is applied to the 60 Hz signal. The magnitude of the modulation signal is 10% and the modulation frequency varies from 1 Hz to 5 Hz at a step of 0.5 Hz. The measurement errors are shown in FIG. 10. The maximum measurement error is about 88 mHz at the modulation frequency of 5 Hz. This is the maximum error among all the tests; however, it is still below the error threshold.

The error is usually related to the window size and the order of the polynomial in (7). A shorter window and higher order of polynomial usually produces a better measurement accuracy under such dynamic condition. An example of reducing L from 60 to 24 is provided in FIG. 11, and we can see that the measurement errors can be reduced significantly. In this case, the maximum error is reduced to below 25 mHz. However, it should be noted that the dynamic accuracy improvement may be at the expense of worse noise reject performance.

### CONCLUSION

According to some embodiments, apparatus, methods and computer readable media enable ultra-fast and high-accuracy frequency measurements for the power grid and other applications. The computational complexity of some embodiments may be O(1), independent of the measurement window size. Some embodiments may provide an extremely low computation cost in comparison to conventional techniques, and a frequency value can be generated using relatively few numbers of numerical operations. Modern digital signal processors can perform one or more numerical operations (e.g. ‘+’, ‘−’, and ‘*’) per microprocessor cycle, thus, a new frequency can be computed by a few microprocessor cycles. Testing results indicate high measurement accuracy is possible.

Frequency measurements according to some embodiments can provide higher resolution of grid visibility for power system event analysis, more reliable grid control/protections. Relatively low computation cost also allows for grid devices to implement embodiments of the inventive subject matter, such that these devices can provide measurements with accuracy comparable to that provided by PMUs. Additionally, as the frequency can be estimated at the same rate as the data sampling rate, the rate of change of frequency can be estimated with a higher accuracy and a high rate.

In the drawings and specification, there have been disclosed typical preferred embodiments of the invention and, although specific terms are employed, they are used in a generic and descriptive sense only and not for purposes of limitation, the scope of the invention being set forth in the following claims.

### APPENDIX

$$\begin{matrix} Derivation of \frac{\partial e}{\partial {α}_{0}} , \frac{\partial e}{\partial {α}_{1}} , and \frac{\partial e}{\partial {α}_{2}} & \\ \frac{\partial \text{?}}{\partial \text{?}} = 2 \text{?} \{ ( p ( i ) - φ ( i ) ) * \frac{\partial p \text{?}}{\partial \text{?}} \} = 2 \text{?} ( p ( i ) - φ ( i ) ) = 2 {α}_{0} ( 2 L + 1 ) + 2 {α}_{1} \text{?} t ( i ) + 2 {α}_{2} \text{?} {t ( i )}^{2} - 2 \text{?} φ ( i ) & ( 32 ) \\ \frac{\partial \text{?}}{\partial \text{?}} = 2 \text{?} \{ ( p ( i ) - φ ( i ) ) * \frac{\partial p \text{?}}{\partial \text{?}} \} = 2 \text{?} \{ ( p ( t ) - φ ( i ) ) t ( i ) \} = 2 {α}_{0} \text{?} t ( i ) + 2 {α}_{1} \text{?} {t ( i )}^{1} + 2 {α}_{2} \text{?} {t ( i )}^{3} - 2 \text{?} φ ( i ) t ( i ) \\ & ( 33 ) \\ \frac{\partial \text{?}}{\partial \text{?}} = 2 \text{?} \{ ( p ( i ) - φ ( i ) ) * \frac{\partial p \text{?}}{\partial \text{?}} \} = 2 \text{?} \{ ( p ( i ) - φ ( i ) ) {t ( i )}^{2} \} = 2 {α}_{0} \text{?} {t ( i )}^{2} + 2 {α}_{1} \text{?} {T ( i )}^{3} + 2 {α}_{2} \text{?} {t ( i )}^{4} - 2 \text{?} φ ( i ) {t ( i )}^{2} \\ \text{?} \text{indicates text missing or illegible when filed} & ( 34 )\end{matrix}$$

Derivation of α₁(j)−α₁(j−1)

According to (25), for j≥1, we have

$$\frac{\text{?} ( j ) - \text{?} ( j - 1 )}{{T}_{22}} = \text{?} φ ( i + j ) \text{?} ( i ) - \text{?} φ ( i + j - 1 ) t ( i ) = \{ φ ( 2 L + j ) t ( 2 L ) + \text{?} φ ( \text{?} + j ) t ( i ) \} - \{ φ ( j - 1 ) t ( 0 ) + \text{?} φ ( i + j - 1 ) t ( i ) \} = \{ φ ( 2 L + j ) t ( 2 L ) - φ ( j - 1 ) t ( 0 ) \} + \{ \text{?} φ ( i + j ) t ( i ) - \text{?} φ ( i + j - 1 ) t ( i ) \} = \{ φ ( 2 L + j ) t ( 2 L ) - φ ( j - 1 ) t ( 0 ) \} + \{ \text{?} φ ( i + j - 1 ) t ( i - 1 ) - \text{?} φ ( i + j - 1 ) t ( i ) \} = \{ φ ( 2 L + j ) t ( 2 L ) - φ ( j - 1 ) t ( 0 ) \} + \text{?} φ ( i + j - 1 ) \{ t ( i - 1 ) - t ( i ) \} \\ \text{?} \text{indicates text missing or illegible when filed} \qquad ( 35 )$$

As t(i)=(i−L)Δt, we can rewrite it, for j≥1 as

$${α}_{1} ( i ) - {α}_{1} ( i - 1 ) = {T}_{22} L Δ t \{ φ ( 2 L + j ) + φ ( j - 1 ) \} - {T}_{22} Δ t \text{?} φ ( i + j - 1 ) \\ \text{?} \text{indicates text missing or illegible when filed} \qquad ( 36 )$$

That which is claimed:

1. A method comprising:
recursively computing respective phasor values from respective ones of a series of signal samples for a node of a power system such that each phasor value is computed from a previously computed phasor value; and
recursively computing frequency values from the phasor values for respective ones of the signal samples.

2. The method of claim 1, wherein recursively computing frequency values comprises:
computing respective phase angle values from respective ones of the phasor values;
recursively computing coefficient values for a polynomial that fits the phase angle values; and
recursively computing the frequency values from the coefficient values.

3. The method of claim 1, wherein recursively computing frequency values comprises:
computing a first phase angle value from a first phasor value for a first sample;
computing a first value for a coefficient of a polynomial that fits the phase angle value from the first phase angle value;
computing a first frequency value for the first sample from the first value for the coefficient;
computing a second phase angle value for a second phasor value for a second sample;
computing a second value for the coefficient from the second phase angle value; and
computing a second frequency value for the second sample from the second value for the coefficient and the first frequency value.

4. The method of claim 1, wherein recursively computing frequency values is preceded by:
computing a plurality of phasor values from a set of signal samples;
computing a plurality of phase angle values from the plurality of phasor values; and
computing a frequency value from the plurality of phase angle values.

5. The method of claim 1, further comprising filtering the frequency values to generate a filtered frequency value.

6. The method of claim 1, wherein the samples are generated at a sampling rate and wherein the phasor values and the frequency values are produced at a rate that is the same as the sampling rate.

7. An apparatus configured to perform the method of claim 1.

8. A computer readable medium having computer instructions embodied therein that, when executed on a data processing device, perform the method of claim 1.

9. A method comprising:
computing a plurality of first phase angle values from a plurality of first signal samples;
computing a first value for a coefficient of a polynomial that fits the first phase angle values;
computing a first frequency value from the first value for the coefficient;
computing a second phase angle value from a second signal sample;
computing a second value for the coefficient from the first value for the coefficient and the second phase angle value; and
computing a second frequency value from the second value for the coefficient.

10. The method of claim 9, wherein computing the plurality of first phase angle values comprises:
recursively computing a plurality of first phasor values for respective ones of the first signal samples such that each of the first phasor values is computed from a previously computed one of the first phasor values; and
computing the plurality of first phase angle values from the first phasor values.

11. The method of claim 10, wherein computing the second phase angle value from the second signal sample comprises:
computing a second phasor value from one of the first phasor values and the second sample; and
computing the second phase angle value from the second phasor value.

12. The method of claim 10, wherein recursively computing the plurality of first phasor values for respective ones of the first signal samples is preceded by computing an initial phasor value from an initial plurality of signal samples using a discrete Fourier transform (DFT) and wherein recursively computing the plurality of first phasor values for respective ones of the first signal samples comprises computing a first one of the first phasor values from the initial phasor value.

13. The method of claim 9, further comprising:
computing a third phase angle value from a plurality of third signal samples;
computing a third value for the coefficient from the second value for the coefficient and the third phase angle value; and
computing a third frequency value from the third value for the coefficient.

14. The method of claim 9, wherein the phase angle values and the frequency values are produced at a rate at which the samples are generated.

15. An apparatus configured to perform the method of claim 9.

16. A computer readable medium having computer instructions embodied therein that, when executed on a data processing device, perform the method of claim 9.

17. An apparatus comprising:
a sensor circuit coupled to a node of an electrical power system and configured to generate a series of samples of a signal at the node; and
a data processor configured to recursively compute respective phasor values from respective ones of a series of signal samples for the node such that each phasor value is computed from a previously computed phasor value and to recursively compute frequency values from the phasor values for respective ones of the signal samples.

18. The apparatus of claim 17, wherein the data processor is configured to recursively compute the frequency values by:
computing respective phase angle values from respective ones of the phasor values;
recursively computing coefficient values for a polynomial that fits the phase angle values; and
computing the frequency values from the coefficient values.

19. The apparatus of claim 17, wherein the data processor recursively computes frequency values by:
computing a first phase angle value from a first phasor value for a first sample;
computing a first value for a coefficient of a polynomial that fits the phase angle value;
computing a first frequency value for the first sample from the first value for the coefficient;
computing a second phase angle value for a second phasor value for a second sample;
computing a second value for the coefficient from the second phase angle value; and
computing a second frequency value for the second sample from the second value for the coefficient.

20. The apparatus of claim 17, wherein the sensor generates the samples at a sampling rate and wherein the data processor produces the phasor values and the frequency values at a rate that is the same as the sampling rate.
